(19) United States
(12) Patent Application Publication
(10) Pub. No.: US 2023/0377970 A1
(43) Pub. Date: Nov. 23, 2023

(54) METHOD FOR DIVIDING A TRANSPARENT WORKPIECE

(71) Applicants: Fraunhofer-Gesellschaft zur Förderung der angewandten Forschung e.V., Munchen (DE); Trumpf Laser- und Systemtechnik Gmbh, Ditzingen (DE)

(72) Inventors: Markus BLOTHE, Jena (DE); Maxime CHAMBONNEAU, Jena (DE); Stefan NOLTE, Jena (DE); Malte KUMKAR, Weimar (DE)

(73) Assignees: Fraunhofer-Gesellschaft zur Förderung der angewandten Forschung e.V., München (DE); Trumpf Laser- und Systemtechnik Gmbh, Ditzingen (DE)

(21) Appl. No.: 18/221,501

(22) Filed: Jul. 13, 2023

Related U.S. Application Data
(63) Continuation of application No. PCT/EP2022/050305, filed on Jan. 10, 2022.

(30) Foreign Application Priority Data
Jan. 14, 2021 (DE) 10 2021 100 675.9

(51) Int. Cl. H01L 21/78; B23K 26/53; B23K 26/0622; H01L 21/268

(52) U.S. Cl. CPC H01L 21/78; B23K 26/53; B23K 26/0622; H01L 21/268; B23K 2103/56

(57) ABSTRACT

The invention relates to a method for dividing a transparent workpiece (1) by means of pulsed laser radiation (2) by way of creating a beam convergence zone (3) in the volume of the workpiece, in which the intensity of the laser radiation (2) exceeds a threshold value for non-linear absorption, wherein the beam convergence zone (3) and the workpiece (1) are moved relative to each other, thereby creating a two-dimensional weakening in the workpiece (1) extending along a predetermined separating line (4), and wherein the workpiece (1) is subsequently divided along the separating line (4). The invention proposes that by selecting the duration of the energy input generated by the non-linear absorption of the pulsed laser radiation and by spatial beam shaping, non-linear propagation of the laser radiation (2) in the volume (1) of the workpiece outside the beam convergence zone (3) is suppressed.

### RELATED APPLICATIONS

This application is a Continuation Patent Application of PCT Patent Application No. PCT/EP2022/050305 having International filing date of Jan. 10, 2022, which claims the benefit of priority of Germany Patent Application No. 10 2021 100 675.9 filed on Jan. 14, 2021. The contents of the above applications are all incorporated by reference as if fully set forth herein in their entirety.

### FIELD AND BACKGROUND OF THE INVENTION

The invention relates to a method for dividing a transparent workpiece by pulsed laser radiation by creating a beam convergence zone in the volume of the workpiece in which the intensity of the laser radiation exceeds a threshold value for non-linear absorption, wherein the beam convergence zone and the workpiece are moved relative to each other, thereby creating a two-dimensional weakening in the workpiece extending along a predetermined separating line, and wherein the workpiece is subsequently divided along the separating line.

The dividing of wafer substrates into chips, i.e. the so-called dicing of wafers, plays an important role in the production of semiconductor devices, which are becoming smaller and more complex. The classical methods of dicing are based on the use of a diamond saw for wafers thicker than 100 μm. For thinner wafers, laser-based methods are increasingly used.

WO 2016/059449 A1 describes a dicing method in which pulsed laser radiation is used to create a beam convergence zone in the volume of the workpiece, i.e. the semiconductor substrate, in which the intensity of the laser radiation locally exceeds a threshold value for non-linear absorption. In the beam convergence zone, multiphoton processes occur accordingly, e.g. in the form of multiphoton ionization or avalanche ionization, which lead to the formation of a plasma. The plasma formation rate increases sharply above a threshold that depends on the material of the workpiece and the parameters of the laser radiation. This is therefore also referred to as “optical breakdown”. The resulting modification and thus processing of the workpiece exhibits high precision, since spatially localized, reproducibly small amounts of energy are introduced into the material. The good spatial localization is primarily achieved by focusing the laser radiation using a high numerical aperture optical probe that is as aberration-free as possible. A beam convergence zone is created in the form of an extended, in the cited print “spiky” focus volume in the direction of the laser beam axis. This beam convergence zone is moved relative to the workpiece to create, as a result, a two-dimensional weakening in the workpiece extending along a predetermined separating line. Possible weakening mechanisms due to the introduced modifications are void and/or crack formation, structural changes of the material of the workpiece, cracks coupled to the modification area in each case, transient or permanent stresses, thermomechanical stresses, stresses due to local volume increases or decreases, solidification cracks, etc. . . . Finally, the actual parting of the workpiece occurs by the application of a small mechanical force or stress, which causes the workpiece to break in the area of weakening, i.e. along the parting line.

Of crucial importance is a uniform modification of the material over and into a given depth of the workpiece. This improves the dividability, production defects such as chipping or material distortion are minimized, and higher edge strengths are achieved. In the known method, the modifications in the workpiece are generated with laser pulses of a pulse duration in the range of 100-15000 fs at a wavelength of 500 nm to 2000 nm wavelength and 10 kHz to 2 MHz repetition rate. In the known method, the beam shaping for creating the beam convergence zone is designed on the basis of undisturbed linear propagation of the laser radiation in the volume of the workpiece. However, at the required fluence to generate the weakening of the material enabling fragmentation, the propagation of the laser radiation within the workpiece is subject to non-linear effects in the aforementioned pulse duration range. At low pulse duration and high energy density, the propagation of the laser radiation in the volume of the workpiece is so strongly disturbed by non-linear effects (e.g. self-focusing as well as two-photon absorption already outside the beam convergence zone) that effective energy coupling into the desired area of the beam convergence zone is prevented to a considerable extent. A defined localization of the energy deposition and the resulting modification of the material of the workpiece cannot be achieved at high peak intensity of the radiation, as it is present at short pulse duration.

With long pulse duration (e.g. >1 ns) and thus lower peak intensity, the material can be modified, but since typically a higher energy is required and diffusion effects become effective, greater damage due to an increased thermally loaded volume is accepted. Accordingly, the result of the separation process is not satisfactory with regard to the quality of the break line.

### SUMMARY OF THE INVENTION

Against this background, the object underlying the invention is to provide an improved method for dividing a transparent workpiece. The above-mentioned mentioned disadvantages of known methods are to be avoided.

The invention achieves this object on the basis of a method of the type indicated at the beginning by suppressing non-linear propagation of the laser radiation in the volume of the workpiece outside the beam convergence zone by selecting the duration of the energy input generated by the non-linear absorption of the pulsed laser radiation in the beam convergence zone and/or by spatial beam shaping.

### BRIEF DESCRIPTION OF THE SEVERAL VIEWS OF THE DRAWINGS

Details and advantages of the invention are apparent from the wording of the claims and from the following description of exemplary embodiments based on the drawings. The drawings show in:

FIG. 1: a schematic illustration of the method according to the invention for splitting or dividing a transparent workpiece;

FIG. 2: a schematic illustration of spatial beam shaping according to the invention;

FIG. 3: repetitive introduction of modification zones with different spacings;

FIG. 4: a process of optimizing the method parameters as a flow chart;

FIG. 5: a process of optimizing the pulse duration as a flow chart;

FIG. 6: Process of optimizing the pulse energy as a flow chart;

FIG. 7: a diagram illustrating the interrelationships of the method parameters with repetitive introduction of the modification zones.

### DESCRIPTION OF SPECIFIC EMBODIMENTS OF THE INVENTION

An aspect of the invention is the consideration of the non-linear propagation characteristics for the introduction of the weakening into the workpiece. In order to suppress, i.e. significantly reduce, non-linear propagation of the laser radiation outside the beam convergence zone, the most optimal possible process parameters are defined with respect to the duration of energy input and/or beam shaping, thereby enabling improved control of energy deposition. In this context, the local energy density in the volume of the workpiece is ultimately controlled by the duration of energy input and improves energy coupling within the beam convergence zone. Damage in the surrounding volume, i.e. outside the beam convergence zone, is minimized. The invention achieves that the lowest possible interaction outside, in particular in the propagation direction of the laser radiation in front of the beam convergence zone is achieved in order to minimize interfering non-linear effects (e.g. self-focusing, non-linear absorption) or other propagation disturbances. It is also ensured that during the duration of non-linear absorption in the beam convergence zone, modifications or zones of high electron density occurring first in the beam direction do not shield more than 50%, preferably not more than 20%, particularly preferably not more than 10% of the incident energy from the parts of the beam convergence zone reached later in the beam direction.

By minimizing the non-linear propagation, a suitable fluence can be achieved in a targeted and defined manner by means of beam focusing in the beam convergence zone. As a result, the desired modification only occurs in this area. The combination of temporal and spatial beam shaping results in a uniform, tailored energy deposition over the entire specified beam convergence zone. As a result, the dividing process is facilitated. Chipping or material stresses are minimized. The quality of the break line edge is improved compared to the prior art.

By targeted selection of the process parameters (amount and duration of energy input, spatial beam shaping), according to the invention, in other words, it is achieved that
a) the intensity threshold for non-linear absorption is exceeded in the beam convergence zone,
b) Power or intensity thresholds for undesirable non-linear effects outside the beam convergence zone are fallen below,
c) the energy required for the desired modification is introduced in a controlled, localized manner so that the desired weakening of the surface in the desired geometry results

Ideally, the wavelength of the laser radiation should be selected such that the linear absorption of the laser radiation in the material of the workpiece is below 20%, better still below 10%, particularly preferably below 5% over a length of one centimeter in the laser beam direction. In addition, the wavelength of the laser radiation should be selected according to the proviso that the non-linear refractive index in the volume of the workpiece at this wavelength is so low that non-linear effects do not prevent sufficient energy deposition in the beam convergence zone. At the same time, the wavelength should lie in a range in which good focusability is ensured.

According to the invention, the suitable choice of the duration of the energy input by the non-linearly induced absorption of the pulsed laser radiation in the beam convergence zone, i.e. at a certain position of the workpiece along the separating line, is crucial. The duration of the energy input can be specified, for example, by the pulse duration of the pulsed laser radiation. An upper limit of the duration results from the tolerable size of the thermal damage zone due to heat diffusion. Furthermore, an upper limit for the duration is given by the maximum tolerable energy absorbed in the beam convergence zone. The greater the duration, the greater the energy input when the intensity is above the threshold value for non-linear absorption. Too much energy and/or energy introduced over too long a period of time will prevent the local limitation of the weakening to the beam convergence zone. In terms of avoiding nonlinear propagation of the laser radiation outside the beam convergence zone, the lower limit of the energy input duration matters. In particular, the pulse duration should be greater than a critical value, where the critical value is, for example, the quotient of pulse energy and material-specific critical power, above which non-linear propagation, in particular self-focusing, occurs in the volume of the workpiece. This ensures that the energy deposition is not excessively disturbed by non-linear effects, thus ensuring a sufficiently high and localized energy deposition in the beam convergence zone.

Appropriately, the duration of energy input (e.g., pulse duration) and the amount of energy input (e.g., pulse energy) in a pulse event should be selected on the proviso that damage, i.e., a desired modification in the volume of the workpiece within the beam convergence zone, occurs by a single laser pulse or a laser pulse burst consisting of a sequence of a predetermined number of laser pulses. A suitable single pulse may be, for example, a laser pulse with a Gaussian temporal profile of specific pulse duration. A burst comprises a predetermined number of laser pulses with a small temporal interval (pulse repetition frequency in the GHz or THz range). If the temporal interval of the bursts from each other is at least 100 times greater than the duration of the individual burst, such a burst is also considered a pulse event. The modification at a particular location on the workpiece should be completely generated during a single such “pulse event” (single pulse or burst). Accordingly, energy input in the context of the invention refers to the energy input during a single pulse event by non-linear induced absorption in the beam convergence zone. The duration of the energy input results accordingly from the pulse duration or the burst duration. It should be noted that the laser pulses do not necessarily have to have a Gaussian shape, a “flat top” shape or any other common shape. Any pulse shape is conceivable. What is decisive is the effective duration of the energy input. In the method according to the invention, this is preferably 20-500 ps.

The two-dimensional weakening is then generated repetitively by moving the workpiece relative to the beam convergence zone incrementally along the parting line from pulse event to pulse event. If possible, the weakening is generated during a single motion event along the parting line. In this way, a high process speed can be achieved and the workpiece breaks reliably with high quality of the dividing edge along the separating line.

In an embodiment, the shortest possible duration of energy input is determined at which the desired modification occurs with a probability of at least 80%, preferably at least 90%, more preferably at least 95%. The duration of energy input when the weakening is introduced is then chosen to be greater than or equal to this determined shortest possible value, which may depend on numerous factors (material, size and geometry of the beam convergence zone, wavelength, pulse shape, etc.). E.g., the selected duration of the energy input can be above the determined shortest possible value by a factor of 10, preferably by a factor of 5, particularly preferably by a factor of 2. Ideally, the factor is in the range of 1.1 to 5. This provides good control of the energy input for the desired generation of the weakening.

The beam convergence zone may have an elongated shape perpendicular to the workpiece surface. Similar to WO 2016/059449 A1 cited above, the beam convergence zone should be elongated in the beam direction and thus extend over most of the full thickness of the workpiece to ensure suitable weakening. For example, the length of the beam convergence zone in the beam direction may be greater than the extent of the beam convergence zone perpendicular to the desired two-dimensional weakening by at least a factor of 10, preferably by at least a factor of 50, particularly preferably by at least a factor of 100. The laser beam can initially have a Gaussian profile or any other feasible input beam shape. Particularly suitable are Gauss-Bessel beams or other beam shapes that can substantially be described as non-diffracting beams. A tailored spatial intensity distribution in the beam convergence zone is expediently achieved by means of suitable optical components, such as focusing optics in combination with beam shaping optics, also with adaptive beam shaping components, such as spatial light modulators (SLM) or piezo mirrors. Improvement can be achieved by depth-dependent aberration correction. The goal of spatial beam shaping is to achieve the most undisturbed energy input possible into the desired beam convergence zone, from the workpiece surface (beam entrance surface) to the depth into the workpiece required for the separation process.

At the same time, the extent of the beam convergence zone transverse to the beam axis should be greater in the direction parallel to the weakening plane than perpendicular to it. This minimizes the portion of the laser radiation that is influenced (shielded) by the above-mentioned introduced modifications during repetitive introduction of the modifications with relative movement of the beam convergence zone and the workpiece.

As mentioned above, the invention aims at achieving the lowest possible interaction outside, in particular in the propagation direction of the laser radiation in front of the beam convergence zone in order to minimize disturbing nonlinear effects. In addition, it should be ensured that during a pulse event in the beam convergence zone, modifications or zones of high electron density that arise first shield only as small a portion as possible of the incident energy from the parts of the beam convergence zone that are reached later. Suitable beam shaping can contribute to this. Beam shaping can advantageously be carried out in such a way that those beam components (consisting of individual beams or bundles of individual beams) of the laser radiation which converge closer to the workpiece surface in the volume of the workpiece enclose an equal or smaller angle with the beam axis than those beam components which converge further away from the workpiece surface in the volume of the workpiece. This should apply in any case to the majority of the beam components converging in the beam convergence zone; the deviation of a small portion of the beam components from this geometry can be tolerated in individual cases, provided that nonlinear effects are sufficiently suppressed.

The method according to the invention is particularly suitable for dicing semiconductor wafers into chips. The temporal and spatial beam shaping proposed by the invention prevents or at least minimizes non-linear propagation of the laser radiation, which is detrimental to the dicing process. As a result, the propagation of the laser radiation in the material of the substrate is undisturbed and an elongated modification zone can be introduced with each pulse event. By repeating the procedure with relative movement of the laser beam and the substrate, a two-dimensional weakening is created along a predetermined separating line. This serves as a predetermined breaking point during fracturing by a subsequently applied tensile stress. Thus, on the one hand thin, but on the other hand even thick semiconductor substrates can be effectively separated with minimized thermally stressed or otherwise impaired breaking point. Due to the small extension of the modification zone transverse to the weakening plane, it is possible to introduce modifications closely adjacent to each other in the feed direction without the beam propagation being significantly disturbed by the above-mentioned introduced modifications. The contour accuracy of the separating line is particularly high. Production errors and rejects are minimized. At the same time, a high process speed can be achieved.

The method according to the invention is also suitable for dividing flat glass products or ceramic and crystalline workpieces.

FIG. 1 illustrates the essential steps of the method according to the invention for splitting or dividing a workpiece 1, for example a wafer in semiconductor manufacturing. A laser beam 2 in the form of pulsed laser radiation is radiated onto the workpiece from above. The laser beam 2 is shaped (e.g. by focusing optics in combination with a spatial light modulator, not shown) in such a way that a beam convergence zone 3 elongated in the beam direction is generated in the volume of the workpiece 1. Within the beam convergence zone 3, the intensity of the laser radiation exceeds the threshold value for non-linear absorption, so that a corresponding spatially limited modification of the material of the workpiece 1 occurs. The beam convergence zone 3 is moved incrementally relative to the workpiece (direction of arrow). In the process, a plurality of modification zones 5 lying next to each other along a separating line 4 are generated in the volume of the workpiece 1, which together form a weakening plane. Subsequently, the workpiece 1 is broken into two parts 1a, 1b along the separating line 4 by applying a small mechanical force. The separating line need not be straight, as in FIG. 1. Separation of the workpiece parts 1a, 1b along a curved separating line is also conceivable.

The core of the invention is the consideration of the non-linear propagation characteristics of the laser radiation 2 for the introduction of the modification zones 5 into the workpiece 1. The propagation of the laser radiation 2 in the volume of the workpiece 1 would be so strongly disturbed by non-linear effects (e.g. self-focusing as well as, two-photon absorption already outside the beam convergence zone) to such an extent that an effective energy coupling, which is limited to the desired area of the beam convergence zone 3 on the one hand, but also fills it as completely as possible on the other hand, is prevented to a considerable extent. In order to suppress, i.e. reduce, such non-linear propagation of the laser radiation 2 outside the beam convergence zone 3, the most optimal possible process parameters are defined in accordance with the invention with regard to the duration of the energy input and beam shaping, thus enabling extensive control of the energy deposition. Damage in the surrounding volume, i.e. outside the beam convergence zone 3, is reduced to a minimum.

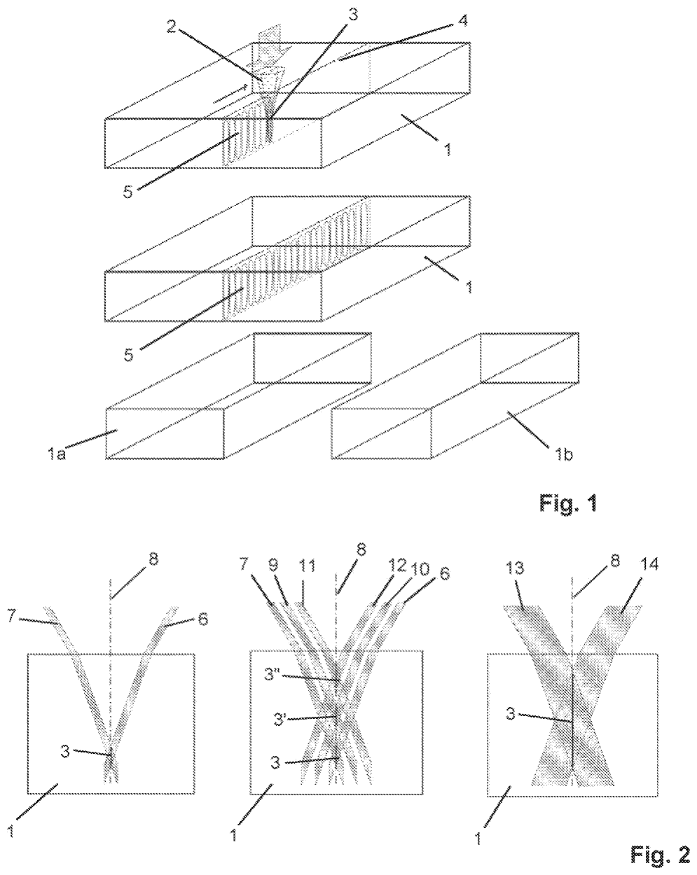

FIG. 2 schematically illustrates the spatial beam shaping according to the invention by means of sections through the workpiece 1. In the left depiction of FIG. 2, two beam components 6, 7 of the laser radiation 2 incident from above (FIG. 1) converge in a beam convergence zone 3 far below the workpiece surface (beam entrance surface). The beam components 6, 7 enclose an acute angle with the beam axis 8, resulting in an elongated beam convergence zone 3. The beam components 6, 7 propagating through the volume of the workpiece 1 at an angle to the beam axis 8 ensure that overlapping of the beam components 6, 7 occurs exclusively in the beam convergence zone 3. Outside the beam convergence zone, the fluence of the laser radiation in the volume of the workpiece remains so low that as few non-linear effects as possible occur. In the middle depiction of FIG. 2, further beam components 9, 10, 11, 12 of the laser radiation 2 (FIG. 1) are added, which “fill up” the area between the lowest beam convergence zone 3 with further beam convergence zones 3′, 3″. To prevent nonlinear propagation of the laser radiation 2 outside the beam convergence zones 3, 3′, 3″, those beam components 9, 10, 11, 12 of the laser radiation 2 which converge closer to the workpiece surface in the volume of the workpiece 1 have an angle with the beam axis 8 which is the same (as in FIG. 2) or smaller than those beam components 6, 7 which converge further away from the workpiece surface in the volume of the workpiece 1. This excludes the possibility that different beam components 6, 7, 9, 10, 11, 12 overlap outside the beam convergence zones 3, 3′, 3″, thereby creating a fluence that enables non-linear effects. In the example of the right depiction of FIG. 2, the various beam components 6, 7, 9 and 10, 11, 12, respectively, merge into each other in two wider beam components 13, 14, so that a single elongated beam convergence zone 3 is formed. Beam shaping ensures that during a pulse event (single laser pulse or pulse burst) in the beam convergence zone 3, modifications (or zones of high electron density) that occur first (i.e., further up in FIG. 2) shield only a small portion of the incident energy from the portions of the beam convergence zone 3 that are reached later (further down). This can generally be achieved by the narrowest possible angular spectrum of the beam components 6, 7, 9, 10, 11, 12, 13, 14 of the incident laser radiation with respect to the beam axis 8.

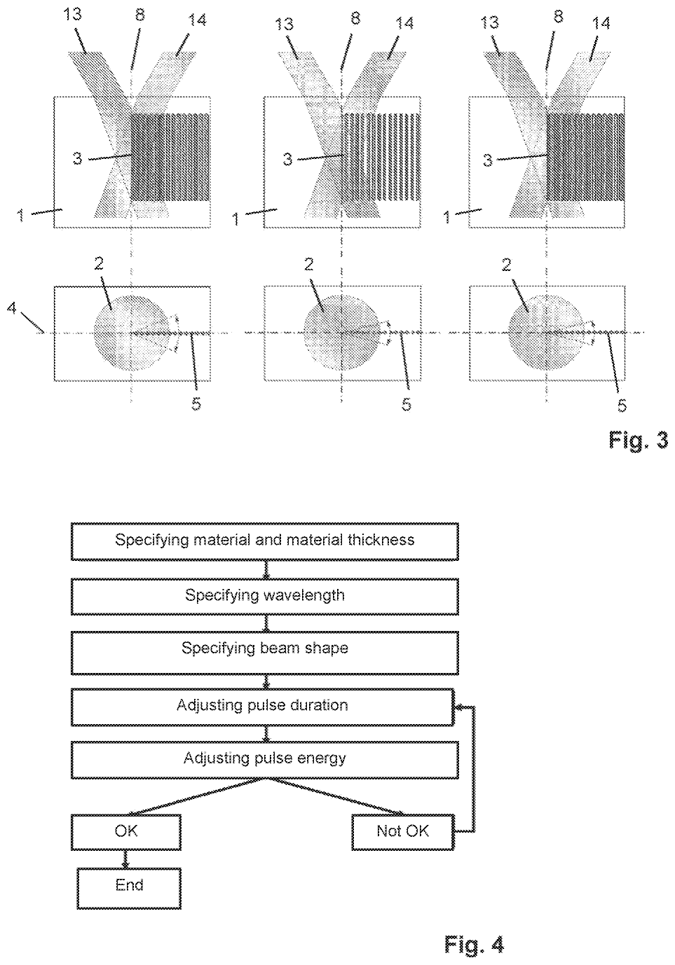

FIG. 3 in turn illustrates, by means of sectional views (upper depictions) and by means of top views (lower depictions) of the workpiece 1, the successive introduction of a plurality of modification zones 5 by the converging beam components 13, 14 of the laser radiation 2. In the process, as explained above, the workpiece 1 is moved relative to the beam convergence zone 3 (to the right in FIG. 3). In the left depiction, the modification zones 5 are introduced in close proximity. In the process, part of the laser radiation 2 is shielded by the respective modification zones 5 already introduced in advance. The corresponding shielding angular segment is shown in the lower depictions of FIG. 3. It can be seen that the angular segment is larger for closely spaced modification zones 5 (left depiction) than for more widely spaced modification zones 5 (middle illustration). In the right depiction, the modification zones are again closely adjacent. However, here the beam shaping occurs in such a way that the extent of the beam convergence zone 3 and, correspondingly, of the modification zone 5 shown in each case is larger transversely to the beam axis 8 in the direction parallel to the weakening plane (i.e. along the separating line 4) than perpendicularly thereto. As a result, that portion of the laser radiation 2 which is shielded by the respective above-mentioned already introduced modification zones 5 during the repetitive introduction of the modification zones 5 is reduced. In the lower right depiction, it can be seen that the shielding angular segment is smaller than in the lower left depiction. The smaller extension of the modification zones 5 transverse to the parting line 4 thus permits closely spaced modification zones, so that overall a larger proportion of the area can be weakened and thus the quality of the fracture can be improved.

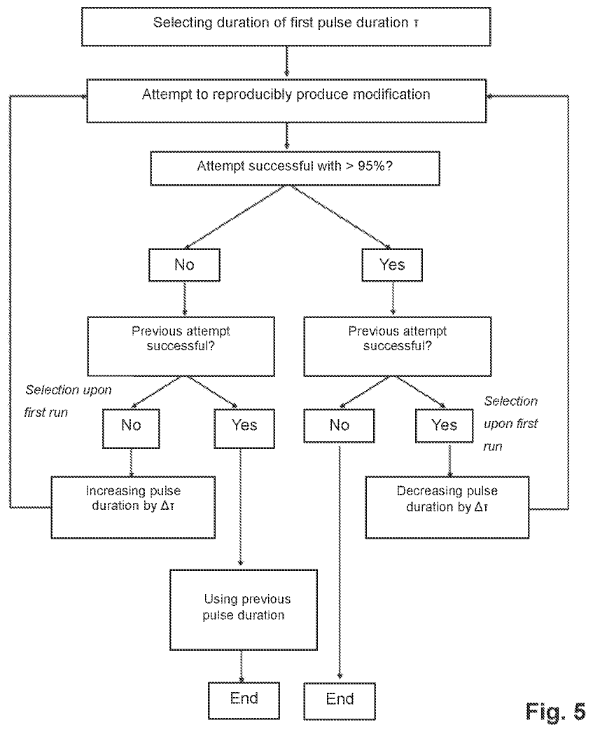

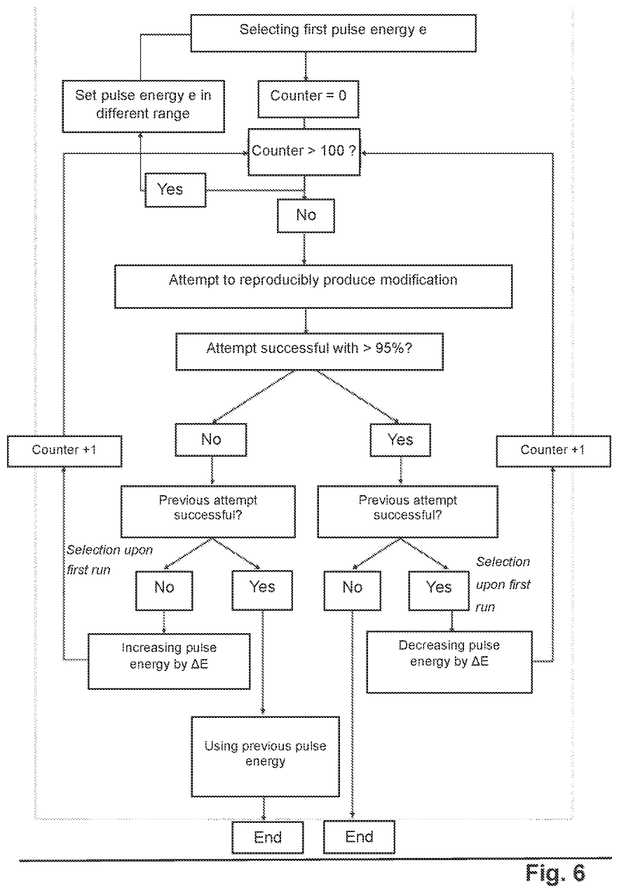

FIG. 4 shows an example of the procedure for optimizing the process parameters according to the invention. First, the wavelength of the laser radiation is specified based on the conditions of the workpiece 1 (material and thickness). Ideally, the wavelength of the laser radiation should be selected so that the linear absorption of the laser radiation in the material of the workpiece is below 20%, better still below 10%, particularly preferably below 5% over a length of one centimeter in the laser beam direction. In addition, the wavelength of the laser radiation should be selected on the proviso that the non-linear refractive index in the volume of the workpiece is as low as possible at this wavelength. For example, a longer wavelength reduces two-photon absorption outside the beam convergence zone. At the same time, the wavelength should be in a range where good focusability is ensured, and a shorter wavelength is preferable from this point of view. Based on the different optimization criteria, a suitable wavelength is specified. In the next step, the beam shaping is determined according to the criteria explained above, also taking into account the thickness and material of the workpiece (refractive index). Then an iterative optimization of pulse duration and pulse energy is carried out, again with the proviso that non-linear effects in the propagation of the laser radiation 2 through the volume of the workpiece 1 outside the beam convergence zone 3 are avoided, or at least reduced. More details on this are explained below with reference to FIGS. 5 and 6.

In order to achieve the best possible control of the energy deposition, the shortest possible duration of the energy input generated by the non-linear absorption of the pulsed laser radiation, i.e. in this case the shortest possible pulse duration for the desired achievement of the modification in the workpiece 1 is determined. This depends on the parameters already determined in advance, namely material, geometry of the beam convergence zone 3, i.e. beam shape and wavelength. The optimization steps shown in FIG. 5 are used to find the optimum pulse duration. A possible starting point for the iterative optimization can result from the necessary energy density for the modification of the material of the workpiece 1 on the one hand and the respective critical power, from which self-focusing of the laser radiation 2 propagating in the volume of the workpiece 1 occurs, on the other hand. The pulse duration must be selected at least long enough so that the peak powers of the laser radiation achieved are below the material-specific parameter critical for self-focusing. Verification of successful modification with at least 95% probability in the sequence shown in FIGS. 5 and 6 is carried out, for example, according to ISO 21254 (“Lasers and laser-related equipment—Test methods for laser-induced damage threshold”). Pulse duration and pulse energy of the pulsed laser radiation 2 are determined by the optimization in such a way that a modification by a single laser pulse or a laser pulse burst consisting of a predetermined sequence of laser pulses occurs reliably (at least 95% probability). At the same time, the minimum necessary pulse duration is selected at which the modification still occurs reliably. After the optimization of the pulse duration according to FIG. 5, the pulse duration can optionally be adjusted upwards depending on the result, if an improved result and/or an increased process stability can be achieved. The upper limit is further determined by the thermal damage range during laser irradiation. According to FIG. 6, the fluence in the desired modification range (>95% probability) is then adjusted by increasing or decreasing the pulse energy in accordance with an analogous procedure. The optimization steps of FIGS. 5 and 6 ensure that an optimum pulse duration and pulse energy are used for the selected beam shaping, i.e. for the desired geometry of the modification zone 5.

In a practical implementation of the invention, a 525 μm thick silicon wafer is irradiated with pulsed laser radiation at a wavelength of 1960 nm. A significant reduction of the non-linear propagation and thus the first occurrence of modifications can be observed from 20 ps pulse duration. The determination of the modification probability by a single laser pulse shows that a probability of >95% is reached from 25 ps pulse duration. In this case, the pulse energy is 15 μJ. Thus, modification zones with a diameter of 5 μm and a length of 350 μm in the beam direction can be generated by means of spatial pulse shaping. The modification zones are aligned with an interval of 10 μm by moving the focus of the laser radiation, i.e. the beam convergence zone, relative to the wafer. Subsequently, the wafer can be broken at right angles with a small mechanical force. An exact break line is formed. The heat-affected area along the break line is small. The roughness of the surface is less than 5 μm.

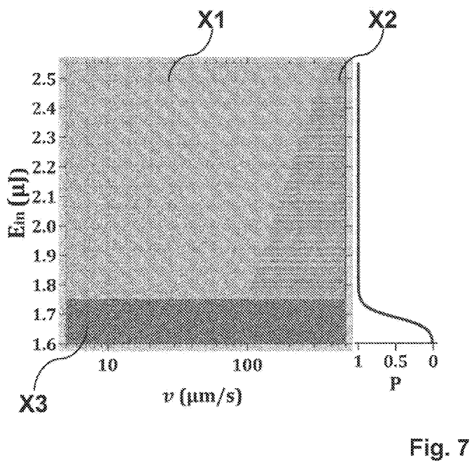

To create a continuous weakening in the material of the workpiece 1, the speed of the relative movement of the laser beam 2 and the workpiece 1 can be lowered to such an extent that there is an overlap of the modification zones 5 in the volume of the workpiece 1. The diagram of FIG. 7 shows how the interaction of the parameters of the feed speed ν, the modification probability P and the input pulse energy Eᵢₙ forms different regimes. X1 denotes the region in which the modifications are introduced in a continuous manner (overlapping each other). At the respective selected energy Eᵢₙ, which has an influence on the extension of the modification zones 5 perpendicular to the beam propagation, an overlap occurs. If the feed rate is increased, then at the same repetition rate of the pulse events, the distances between the introduced modification zones 5 are increased and the formation of separated, i.e. non-overlapping modification zones 5 occurs (regime X2). In regime X3, the pulse energy is too low, so that the probability of modification is too low. Sufficient weakening of the workpiece 1 to allow fracture is not achieved.

1. A method for dividing a transparent workpiece by means of pulsed laser radiation by way of creating a beam convergence zone in the volume of the workpiece, in which the intensity of the laser radiation exceeds a threshold value for non-linear absorption, wherein the beam convergence zone and the workpiece are moved relative to each other, thereby creating a two-dimensional weakening in the workpiece extending along a predetermined separating line, and wherein the workpiece is subsequently divided along the separating line, wherein non-linear propagation of the laser radiation in the volume of the workpiece outside the beam convergence zone is suppressed by selecting the duration of the energy input generated by the non-linear absorption of the pulsed laser radiation in the beam convergence zone and/or by spatial beam shaping.

2. Method according to claim 1, wherein the wavelength of the laser radiation is selected according to the proviso that the linear absorption of the laser radiation at this wavelength is less than 20% per centimeter, preferably less than 10%, particularly preferably less than 5% per centimeter.

3. Method according to claim 2, wherein the wavelength of the laser radiation is selected according to the proviso that the non-linear refractive index in the volume of the workpiece at this wavelength is as low as possible, in particular so low that non-linear propagation does not prevent an energy input sufficient to create the weakening into the beam convergence zone.

4. Method according to claim 1, wherein the pulse duration of the pulsed laser radiation is greater than a critical value, wherein the critical value is the quotient of pulse energy and material-specific critical power above which non-linear propagation, in particular self-focusing, occurs in the volume of the workpiece.

5. Method according to claim 1, wherein the pulse duration and the pulse energy of the pulsed laser radiation are selected according to the proviso that a modification is effected by the non-linear absorption of the laser radiation in the volume of the workpiece within the beam convergence zone by a single laser pulse or a laser pulse burst consisting of a sequence of a predetermined number of laser pulses.

6. Method according to claim 1, wherein a shortest possible duration of energy input is determined at which the modification occurs with a probability of at least 80%, preferably at least 90%, particularly preferably at least 95%, wherein the duration of energy input is selected such that it is greater than or equal to this determined shortest possible value, preferably greater by a factor of 1-20, particularly preferably by a factor of 1.1-5.

7. Method according to claim 1, wherein the beam convergence zone has an elongated shape along the beam axis oriented substantially perpendicular to the workpiece surface, wherein the length of the beam convergence zone in the beam direction is greater by at least a factor of 10, preferably by at least a factor of 50, particularly preferably by at least a factor of 100, than the extent of the beam convergence zone perpendicular thereto.

8. Method according to claim 7, wherein the extent of the beam convergence zone transverse to the beam axis is greater in the direction parallel to the weakening plane than perpendicular thereto, preferably greater by more than 1.2 times, particularly preferably greater by more than 2 times.

9. Method according to claim 8, wherein the beam shaping is performed in such a way that those beam components of the laser radiation which converge closer to the workpiece surface in the volume of the workpiece enclose an equal or smaller angle with the beam axis than those beam components which converge further away from the workpiece surface in the volume of the workpiece.

10. Method according to claim 1, wherein the material of the workpiece is silicon, wherein the pulse duration of the pulsed laser radiation is in the range of 20-500 ps and wherein the wavelength of the laser radiation is in the range of 1300-2500 nm.

11. Method according to claim 1, wherein the workpiece is a semiconductor wafer which is divided into chips along one or more separating lines.
